(19) United States
(12) Patent Application Publication
(10) Pub. No.: US 2009/0260572 A1
(43) Pub. Date: Oct. 22, 2009

(54) CHEMICAL VAPOR DEPOSITION APPARATUS

(75) Inventors: Changsung Sean Kim, Yongin (KR); Sang Duk Yoo, Seongnam (KR); Jong Pa Hong, Yongin (KR); Won Shin Lee, Seoul (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 12/263,781

(22) Filed: Nov. 3, 2008

(30) Foreign Application Priority Data
Apr. 18, 2008 (KR) 10-2008-0036095

(51) Int. Cl. C23C 16/455; C23C 16/458

(52) U.S. Cl. 118/730; 118/715

(57) ABSTRACT

There is provided a chemical vapor deposition apparatus including: a chamber including a reactor where a deposition object is deposited; a first supplier including a plurality of gas pipes allowing a first gas to be jetted into the reactor in a substantially horizontal direction; a second supplier including a plurality of holes of a predetermined size having the gas pipes inserted therein, respectively; a supply flow path formed between each of the gas pipes and each of the holes, the supply flow path allowing a second gas to be supplied into the reactor in a substantially horizontal direction.

### CROSS-REFERENCE TO RELATED APPLICATIONS

This application claims the priority of Korean Patent Application No. 2008-36095 filed on Apr. 18, 2008, in the Korean Intellectual Property Office, the disclosure of which is incorporated herein by reference.

### BACKGROUND OF THE INVENTION

1. Field of the Invention

The present invention relates to a chemical vapor deposition apparatus, and more particularly, to a chemical vapor deposition apparatus structured such that a reaction gas is jetted with higher efficiency.

2. Description of the Related Art

In general, chemical vapor deposition (CVD) is a process in which a reaction gas fed into a reaction chamber reacts chemically on a top surface of a heated wafer to grow a thin film. This thin film growth method ensures crystals to be grown with better quality than a liquid phase growth. However, disadvantageously, the crystals are grown at a relatively slow rate. A widely used method for overcoming this drawback is to grow the crystals on several substrates simultaneously in one growth cycle.

A conventional chemical vapor deposition apparatus includes a reaction chamber having an inner space of a predetermined size, a susceptor installed in the inner space to mount a wafer as the deposition object thereon, a heater disposed adjacent to the susceptor to apply predetermined heat, and a gas supplier jetting a reaction gas into the reaction chamber to allow the wafer to be deposited.

A reaction gas necessary for chemical vapor deposition includes a combination of various gases, some of which chemically react before being fed into the reaction chamber in a mixed state. Therefore, it may be undesirable to mix various gases into a reaction gas and supply the reaction gas to the reaction chamber at one time.

Consequently, the reaction gas fed into the reaction chamber may be separated into at least two to be fed into the reaction chamber individually such that the gases are mixed together inside the reactor.

However, conventionally, in order to supply such separate gases into the reactor individually, separate structures for gas supply should be provided. However, this causes the reaction gas to be supplied in a very limited amount at one time and renders the reaction gases supplied separately hardly miscible with each other.

### SUMMARY OF THE INVENTION

An aspect of the present invention provides a chemical vapor deposition apparatus which overcomes spatial limitation caused by supplying separate gases individually not to react in advance, but allows the gases to be supplied separately in a great amount at one time and the supplied gases to be mixed fast inside the chamber, thereby ensuring deposition is performed with better reliability.

According to an aspect of the present invention, there is provided a chemical vapor deposition apparatus including: a chamber including a reactor where a deposition object is deposited; a first supplier including a plurality of gas pipes allowing a first gas to be jetted into the reactor in a substantially horizontal direction; a second supplier including a plurality of holes of a predetermined size having the gas pipes inserted therein, respectively; a supply flow path formed between each of the gas pipes and each of the holes, the supply flow path allowing a second gas to be supplied into the reactor in a substantially horizontal direction.

The chemical vapor deposition apparatus may further include an outlet opening provided in a center of the reactor to exhaust a reaction gas, wherein the reactor is provided at an outer edge thereof with the first and second suppliers.

The chemical vapor deposition apparatus may further include a first gas room provided between a side end portion of the chamber and the first supplier disposed inward from the side end portion of the chamber to have a predetermined gap therebetween.

The chemical vapor deposition apparatus may include a second gas room provided between the first supplier and the second supplier disposed inward from the first supplier to have a predetermined gap therebetween.

The first and second gas rooms may be separated from each other by the first supplier.

The supply flow path may be defined by a gap of a predetermined size between an inner surface of the hole and an outer surface of the gas pipe.

The chemical vapor deposition apparatus may further include a third supplier disposed between the first and second suppliers, wherein the second gas room is formed between the third supplier and the second supplier and the third gas room is formed between the third supplier and the first supplier.

The third supplier may include a plurality of supply pipes hollowed to have the gas pipes inserted therein, each of the supply pipes allowing a third gas of the third gas room to be introduced to the reactor by keeping the third gas room and the reactor in communication with each other.

The supply flow path may include: a first supply flow path formed between the each of the holes and each of the supply pipes to allow a second gas of the second gas room to be supplied, and a second supply flow path formed between the supply pipe and the gas pipe to allow the third gas of the gas room to be supplied.

The first supply flow path may be defined by a gap of a predetermined size between an inner surface of the hole and an outer surface of the supply pipe, and the second supply flow path is defined by a gap of a predetermined size between an inner surface of the supply pipe and an outer surface of the gas pipe.

The chemical vapor deposition apparatus may further include a plurality of outlet openings at an outer edge of the reactor to exhaust a reaction gas, wherein the reactor is provided in a center thereof with the first and second suppliers.

The chemical vapor deposition apparatus may further include a first gas room disposed inward from the first supplier.

The chemical vapor deposition apparatus may further include a second gas room formed between the first and second suppliers, the second supplier surrounding the first supplier to have a predetermined gap therebetween.

The supply flow path may be defined by a gap of a predetermined size between an inner surface of the hole and an outer surface of the gas pipe.

The flow path may be defined by a gap of a predetermined size between an inner surface of the holes and an outer surface of the gas pipes.

The chemical vapor deposition apparatus may further include a third supplier disposed between the first and second suppliers, wherein the second gas room is formed between the third supplier and the second supplier and the third gas room is formed between the third supplier and the first supplier.

The third supplier may include a plurality of supply pipes hollowed to have the gas pipes inserted therein, each of the supply pipes allowing a third gas of the third gas room to be introduced to the reactor by keeping the third gas room and the reactor in communication with each other.

The supply flow path may include: a first supply flow path formed between the each of the holes and each of the supply pipes to allow a second gas of the second gas room to be supplied, and a second supply flow path formed between the supply pipe and the gas pipe to allow the third gas of the gas room to be supplied.

The first supply flow path may be defined by a gap of a predetermined size between an inner surface of the hole and an outer surface of the supply pipe, and the second supply flow path is defined by a gap of a predetermined size between an inner surface of the supply pipe and an outer surface of the gas pipe.

The chemical vapor deposition apparatus may further include: a first inlet formed in communication with the first gas room and allowing the first gas to be fed to the first gas room, and a second inlet surrounding the first inlet to have a predetermined gap therebetween, the second inlet allowing the second gas to be fed to the second gas room through the gap with the first inlet.

The first inlet may be formed integral with the first supplier and the second inlet is formed integral with the second supplier.

The chemical vapor deposition apparatus may further include: a first inlet formed in communication with the first gas room and allowing the first gas to be fed to the first gas room, a second inlet surrounding the first inlet to have a predetermined gap therebetween, the second inlet formed in communication with the second gas room to allow the second gas to be fed to the second gas room, and a third inlet inserted with a predetermined gap from the second inlet and surrounding the first inlet to have a predetermined gap therebetween, the third inlet allowing the third gas to be fed to the third gas room through the gap with the first inlet.

The first inlet may be formed integral with the first supplier, the second inlet is formed integral with the second supplier and the third inlet is formed integral with the third supplier.

The chemical vapor deposition apparatus may further include: a susceptor accommodating the deposition object inside the chamber; and a rotational axis passing through the first gas room to rotate the susceptor.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a side cross-sectional perspective view illustrating a chemical vapor deposition apparatus according to an exemplary embodiment of the invention;

FIG. 2 is a detailed magnified view illustrating an A portion shown in FIG. 1;

FIG. 3 is a view illustrating an A portion shown in FIG. 1 having a different structure according to an exemplary embodiment of the invention;

FIG. 4 is a side cross-sectional view illustrating a chemical vapor deposition apparatus according to another exemplary embodiment of the invention;

FIG. 5 is a detailed magnified view illustrating a B portion shown in FIG. 4; and

FIG. 6 is a view illustrating a B portion shown in FIG. 4 having a different structure according to an exemplary embodiment of the invention.

### DETAILED DESCRIPTION OF THE PREFERRED EMBODIMENT

Exemplary embodiments of the present invention will now be described in detail with reference to the accompanying drawings.

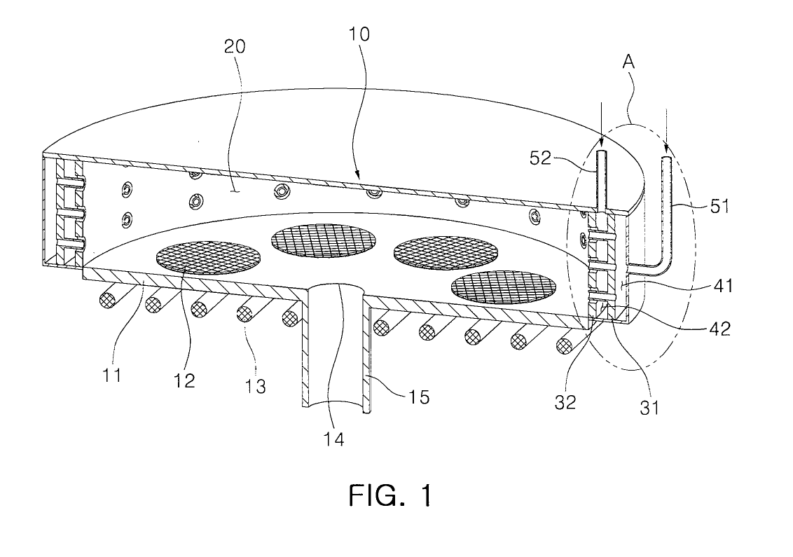

First, referring to FIG. 1, a general structure of a chemical vapor deposition apparatus according to an exemplary embodiment of the invention will be described. FIG. 1 is a side cross-sectional perspective view illustrating a chemical vapor deposition apparatus according to an exemplary embodiment of the invention.

As shown in FIG. 1, the chemical vapor deposition apparatus of the present embodiment includes a chamber 10 where a reactor 20 is disposed, a susceptor 11 disposed inside the reactor 20, deposition objects 12 placed on the susceptor 11 and a heater 13 provided at a predetermined distance from a bottom end of the susceptor 11.

The reactor 20 provided inside the chamber 10 has an inner space of a predetermined space so that a reaction gas fed into the reactor chemically reacts with the deposition objects. The reactor may be provided on an inner surface thereof with a heat insulating material to withstand a high temperature atmosphere.

The susceptor 11 as a supporting structure has at least one pocket on a top surface thereof to mount a corresponding one of the deposition objects 12 thereon and is disposed in the reactor 20.

The susceptor 11 is formed of graphite in a substantially disc shape. The susceptor has a driving motor and a rotational axis joined to each other in a central portion of a bottom surface thereof so as to be rotated at a predetermined rate.

The heater 13 is disposed adjacent to the susceptor 11 and applies heat toward the susceptor 11 to heat the deposition objects 12. This heater 130 includes an electric heater, a high frequency inductor, an infrared radiator, a laser and the like.

Also, as shown in FIG. 1, the chemical vapor deposition apparatus of the present embodiment includes a first supplier 31 and a second supplier 32 formed on an outer side of the reactor 20 to supply a first gas and a second gas into the reactor 20, respectively.

A first gas room 41 and a second gas room 42 are disposed inward from a side end portion of the chamber 10. The first gas room 41 is provided between the side end portion of the chamber 10 and the first supplier 31 and the second gas room 42 is provided between the first supplier 31 and the second supplier 32.

That is, the first supplier 31 and the second supplier 32 formed inward from the side end portion of the chamber 10 separate the first gas room 41 and the second gas 42 from each other to have a predetermined gap therebetween in a vertical direction.

As shown in FIG. 1, the first supplier 31 and the second supplier 32 may be sequentially disposed in a circumferential direction along the reactor 20.

Also, the chemical vapor deposition apparatus of the present embodiment includes a first inlet 51 guiding the first gas to the first gas room 41 and a second inlet 52 guiding the second gas to the second gas room 42.

The first gas introduced to the first gas room 41 and the second gas introduced to the second gas room 42 may include gases of different kinds, or gases of partially identical kinds.

Moreover, the first inlet 51 may be formed of a singular one or at least two. That is, at least two first inlets may be disposed with a predetermined gap therebetween to allow the first gas to be introduced to the first gas room 41 simultaneously. This ensures the gas to be fed into the reactor more uniformly.

Likewise, the second inlet 52 maybe formed of a singular one or at least two. The second inlet 52 formed of at least two allows the second gas to be fed into the reactor 20 more uniformly.

Meanwhile, as shown in FIG. 1, the chemical vapor deposition apparatus of the present embodiment includes an outlet opening 14 formed in a center of the reactor 20 to exhaust a reaction gas, and exhaust pipes 15 formed to allow the gas to be exhausted through the outlet opening 14.

Therefore, the chemical vapor deposition apparatus according to the present embodiment shown in FIG. 1 is structured such that the reaction gas is jetted in a centripetal direction and exhausted through the outlet opening 14 formed in the center of the reactor 20.

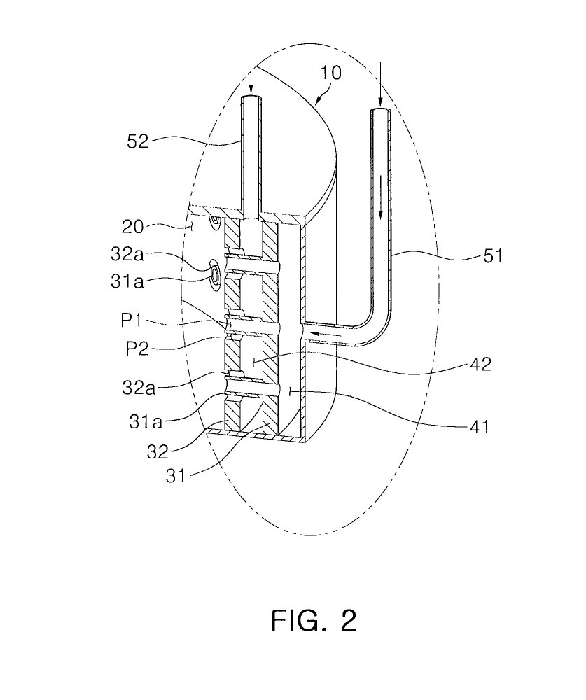

Meanwhile, referring to FIG. 2, a detailed description will be given of major features of the chemical vapor deposition apparatus of the present embodiment shown in FIG. 1. FIG. 2 is a magnified view of an A portion shown in FIG. 1.

As shown in FIG. 2, in the chemical vapor deposition apparatus of the present embodiment, the first supplier 31 includes a plurality of gas pipes 31a through which the first gas room 41 and the reactor 20 are in communication with each other.

The gas pipes 31a may be formed integral with the first supplier 31. Alternatively, the gas pipes 31a alone may be manufactured to be joined to the first supplier 31.

A gas flow path P1 is formed in a center of each of the gas pipes to be in communication with the first gas room 41 so that the first gas can flow to the reactor 20 therethrough.

Also, the second supplier 32 is provided with a plurality of holes 32a of a predetermined size into which the gas pipes 31a are inserted. The holes 32a are substantially identical in number to the gas pipes 31a.

Each of the holes 32a should have a diameter greater than a diameter of each of the gas pipes 31a. As shown in FIG. 2, a supply flow path P2 may be formed between an inner surface of the hole 32a and an outer surface of the gas pipe 31a to be in communication with the second gas room 42 so that the second gas can flow to the reactor 20 therethrough.

Also, to separate the first gas room 41 and the second gas room 42 substantially from each other, the gas pipe 31a may have a length identical to or greater than a length that covers a width of the second gas room 42 and a thickness of the hole 32a of the second supplier 32.

Moreover, to ensure the first gas supplied from the reactor 20 through the gas pipe 32a to be easily mixed with the second gas supplied through the supply flow path P2, the gas pipe 31a may have a length substantially identical to a length that covers a width of the second gas room 42 and a thickness of the hole 32a of the second supplier 32.

Meanwhile, a chemical vapor deposition apparatus will be described according to another exemplary embodiment of the invention.

In the present embodiment, the structures of a chamber 10 where a reactor 20 is provided, a susceptor 11, a heater 13 and an outlet opening 14 are substantially identical to the embodiment shown in FIG. 1, and thus will not be described in further detail.

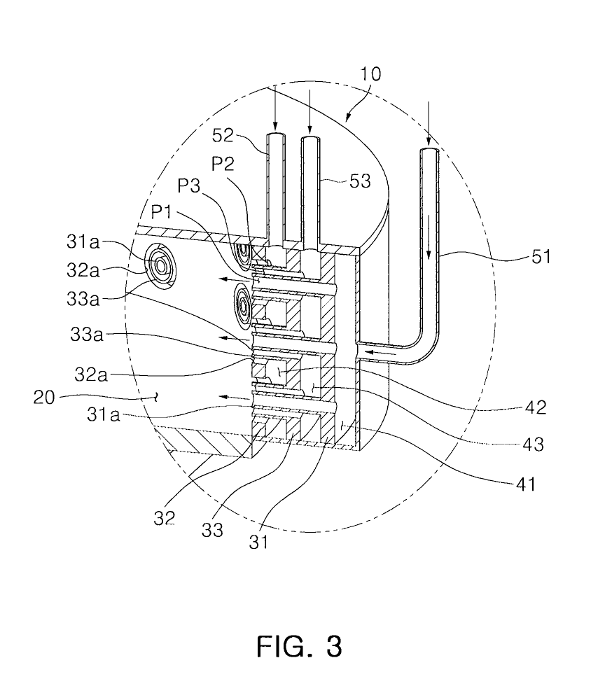

The present embodiment is different from the embodiment shown in FIGS. 1 and 2 in the supply structure of the reaction gas, which will be described in more detail with reference to FIG. 3.

As shown in FIG. 3, a first supplier 31 and a second supplier 32 are formed on an outer side of the reactor 20. Here, the first and second suppliers 31 and 32 are sequentially disposed inward from a side end portion of the chamber and a third supplier 33 is disposed between the first and second suppliers 31 and 33.

A first gas room 41 is formed between the first supplier 31 and the side end portion of the chamber 10. A third gas room 43 is formed between the first supplier 31 and the third supplier 33, and a second gas room 42 is formed between the third supplier 33 and the second supplier 32.

The first gas room 41 is connected to a first inlet 51 so that the first gas is introduced through the first inlet 51. The second gas room 42 is connected to a second inlet 52 so that the second gas is introduced through the second inlet 52. The third gas room 43 is connected to a third inlet 53 so that a third gas is introduced through the third inlet 53. Like the first inlet 51 and the second inlet 52, the third inlet 53 may be formed of a singular one or at least two.

The first, second and third gases may be formed of different gases from one another but may contain partially identical gas components.

The first supplier 31 is provided with gas pipes 31a, the third supplier 33 is provided with supply pipes 33a and the second supplier 32 is provided with holes 32a.

The gas pipes 31a maybe formed integrally with or joined to the first supplier 31. The supply pipes 33a may be formed integrally with or joined to the third supplier 33.

Each of the gas pipes 31a may have a diameter smaller than a diameter of each of the supply pipes 33a. The gas pipes 31a are inserted into the supply pipes 33a to have a predetermined gap therebetween.

Moreover, the supply pipes 33a having the gas pipes 31a inserted thereinto are inserted in the holes 32a. Here, an outer surface of the supply pipe 33a and an inner surface of the hole 32a may have a gap of a predetermined size therebetween.

Here, the chemical vapor deposition apparatus of the present embodiment includes a first supply flow path P2 defined by the gap between the hole 32a and the supply pipe 33a and a second supply flow path P3 defined by the gap between the gas pipe 31a and the supply pipe 33a.

P1 indicated in FIG. 3 denotes a gas flow path passing through the gas pipe 31a.

The gas flow path P keeps the first gas room 41 and the reactor 20 in communication with each other so that the first gas can flow to the reactor 20. The first supply flow path P2 keeps the second gas room 42 and the reactor 20 in communication with each other so that the second gas can flow to the reactor 20. The second supply flow path P3 keeps the third gas room 43 and the reactor 20 in communication with each other so that the third gas can flow to the reactor 20.

To ensure formation of the gas flow path P1 and the supply flow paths P2 and P3, separation of the first gas room 41, the second gas room 42 and the third gas room 43 from one another, and easy mixture of gases, the gas pipe 31a may have a length substantially identical to a length that covers a sum of a width of the second gas room 42 and a thickness of the third supplier 33, and a sum of a width of the second gas room 42 and a thickness of the second supplier 32, respectively. Also, the supply pipe 33a has a length substantially identical to a length that covers a sum of a width of the second gas room 42 and a thickness of the second supplier 32.

That is, an end portion of the hole 32a leading to the reactor 20, an end portion of the supply pipe 33a leading to the reactor 20 and an end portion of the gas pipe 31a leading to the reactor may be located at substantially identical positions.

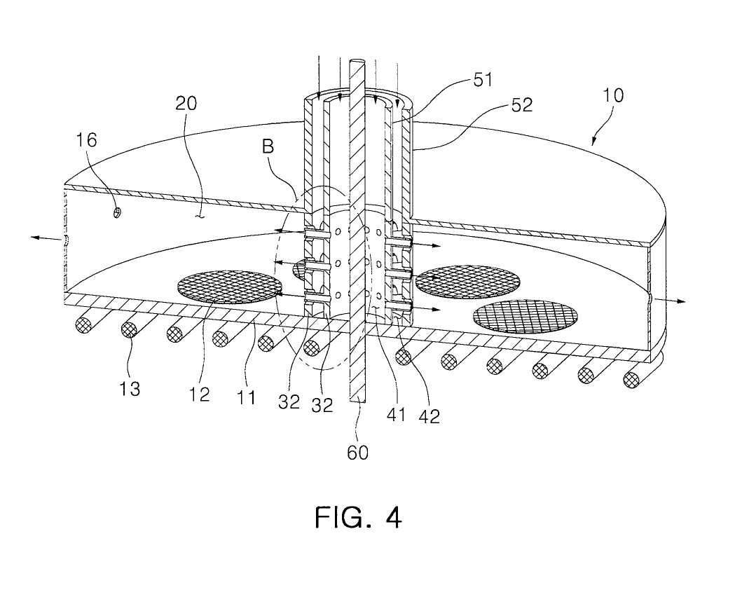

Hereinafter, a chemical vapor deposition apparatus will be described with reference to FIG. 4 according to another exemplary embodiment of the invention. FIG. 4 is a side cross-sectional perspective view illustrating a chemical vapor deposition apparatus according to another exemplary embodiment of the invention.

As shown in FIG. 4, the chemical vapor deposition apparatus according to the present embodiment includes a chamber where a reactor 20 is provided, a susceptor 11 disposed inside the reactor 20, a deposition object 12 placed on the susceptor 11, and a heater 13 disposed below the susceptor 11.

Also, a first supplier 31 and a second supplier 32 are provided in a center of the reactor 20 to supply a reaction gas. In the present embodiment, the first supplier 31 is inserted into the second supplier 32 to have a predetermined gap therebetween.

A first gas room 41 and a second gas room 42 are formed outward from the center of the reactor 20. The first gas room 41 is located near the center of the reactor 20 and the second gas room 42 is located more outward. The first gas room 41 is provided in a hollow inner space of the first supplier 31 and the second gas room 42 is provided in the gap between the first supplier 31 and the second supplier 32.

That is, the first supplier 31 and the second supplier 32 are formed outward from the center of the reactor 20 to have a predetermined gap therebetween in a vertical direction to form the first gas room 41 and the second gas room 42, respectively.

As shown in FIG. 4, the first supplier 31 and the second supplier 32 may be formed in a cylindrical shape in the center of the second supplier 32.

Also, a first inlet 51 is provided to introduce a first gas to the first gas room 41 and a second inlet 52 is provided to introduce a second gas to the second gas room 42.

Here, the first inlet 51 can be joined to or formed integrally with the first supplier 31 and the second inlet 52 can be joined to or formed integrally with the second supplier 32.

The first gas introduced to the first gas room 41 and the second gas introduced to the second gas room 42 contain gases of different kinds from each other, but may contain gases of partially identical kinds.

Meanwhile, as shown in FIG. 4, in the chemical vapor deposition apparatus of the present embodiment, a plurality of holes 16 are provided at a side end portion of the chamber 10 to exhaust the reaction gas therethrough.

Accordingly, the chemical vapor deposition apparatus of the present embodiment shown in FIG. 4 is structured such that the reaction gas is jetted in a centrifugal direction, i.e., radially and exhausted through the exhaust holes 16.

The chemical vapor deposition apparatus of the present embodiment shown in FIG. 4 includes a rotational axis 60 passing through the first gas room 41 formed between the side end portion of the chamber 10 and the first supplier 31 and then joined to the susceptor 11. The rotational axis 60 transfers a rotational force for rotating the susceptor 11.

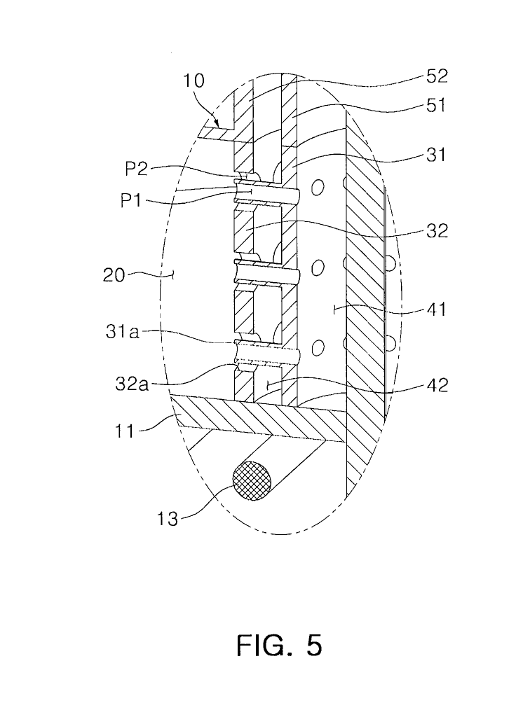

Meanwhile, with reference to FIG. 5, major features of the chemical vapor deposition apparatus of the present embodiment shown in FIG. 5 will be described in more detail. FIG. 5 is a magnified view of a B portion shown in FIG. 4.

As shown in FIG. 5, in the chemical vapor deposition apparatus of the present embodiment, the first supplier 31 includes a plurality of gas pipes 31a through which the first gas room 41 and the reactor 20 are in communication with each other.

The gas pipes 31a can be formed integrally with the first supplier 31. Alternatively, the gas pipes 31a alone may be manufactured to be joined to the first supplier 31.

A gas flow path P1 is formed in a center of each of the gas pipes 31a to be in communication with the first gas room 41 so that the first gas can flow to the reactor 20.

Also, the second supplier 32 includes a plurality of holes 32a of a predetermined size into which the gas pipes 31a are inserted. The number of holes 32a may be substantially identical to the number of the gas pipes 31a.

Each of the holes 32a should have a diameter greater than a diameter of each of the gas pipes 31a. As shown in FIG. 2, a supply flow path P2 may be formed between an inner surface of the hole 32a and an outer surface of the gas pipe 31a to be in communication with the second gas room 42 so that the second gas can flow to the reactor.

To substantially separate the first gas room 41 and the second gas room 42 from each other, the gas pipe 31a may have a length substantially identical to or greater than a length that covers a sum of a width of the second gas room 42 and a thickness of the hole 32a of the second supplier 32.

Moreover, to ensure the first gas fed from the reactor 20 through the gas pipe 32a to be easily mixed with the second gas fed through the supply flow path P2, the gas pipe 31a may have a length substantially identical to a length that covers a sum of a width of the second gas room 42 and a thickness of the hole 32a of the second supplier 32.

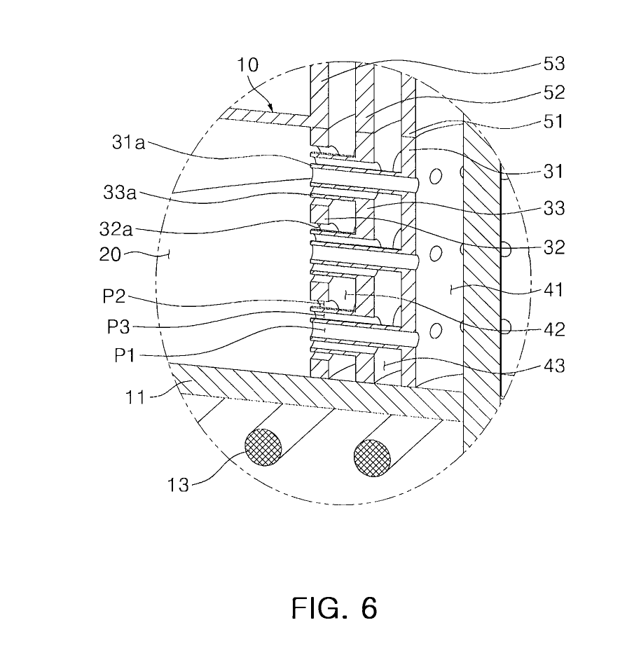

Hereinafter, a chemical vapor deposition apparatus according to still another exemplary embodiment of the invention will be described with reference to FIG. 6.

The present embodiment is substantially identical to the embodiment shown in FIG. 4 when it comes to the structures of a chamber 10 where a reactor 20 is provided, a susceptor 11, a heater 13 and an outlet opening 14, and thus such structures will not be described in further detail.

However, the present embodiment is different from the present embodiment shown in FIGS. 4 and 5 in a supply structure of a reaction gas, which will be described in more detail with reference to FIG. 6.

As shown in FIG. 6, a first supplier 31 and a second supplier 32 are disposed outward from a center of the reactor 20, and a third supplier 33 is formed therebetween.

That is, the third supplier 33 is inserted into the second supplier 32 to have a predetermined gap therebetween and the first supplier 31 is inserted into the third supplier 33 to have a predetermined gap therebetween.

A first gas room 41 is defined by a hollow inner space of the first supplier 31 and a third gas room 43 is formed between the first supplier 31 and the third supplier 33. Also, a second gas room 42 is formed between the third supplier 33 and the second supplier 32.

Therefore, the first supplier 31, the second supplier 32, and the third supplier 33 may be formed in a cylindrical shape. The third supplier 33 should have a diameter greater than a diameter of the first supplier 31 and be sized such that the third gas room 43 can be formed between the third supplier 33 and the first supplier 31.

Moreover, the second supplier 32 should have a diameter greater than a diameter of the third supplier 33 and be sized such that the second gas room 42 is formed between the second supplier 32 and the third supplier 33.

The first gas room 41 is connected to the first inlet 51 so that the first gas is fed through the first inlet 51. The second gas room 42 is connected to the second inlet 52 so that the second gas is fed through the second inlet 52. The third gas room 43 is connected to the third inlet 53 so that the third gas is fed through the third inlet 53.

Here, the first inlet 51, the second inlet 52 and the third inlet 53 are formed integral with the first supplier 31, the second supplier 32 and the third supplier 33, respectively. Alternatively, the first, second and third inlets 51, 52, and 53 may be joined to the first, second and third suppliers 31, 32 and 33, respectively.

The first gas, the second gas and the third gas may include gases of different kinds from one another, or partially identical gas components.

Meanwhile, a gas pipe 31a is provided in the first supplier 31 and a supply pipe 33a is provided in the third supplier 33. Also, a hole 32a is formed in the second supplier 32.

The gas pipe 31a may be formed integral with or joined to the first supplier 31. The supply pipe 33a may be formed integral with or joined to the third supplier 33.

The gas pipe 31a may have a diameter smaller than the supply pipe 33a. The gas pipe 31a is inserted into the supply pipe 33a to have a predetermined gap therebetween.

Also, the supply pipe 33a having the gas pipe 31a inserted thereinto is inserted into the hole 32a to have a gap of a predetermined size between an outer surface of the supply pipe 33a and an inner surface of the hole 32a.

Here, the chemical vapor deposition apparatus of the present embodiment includes a first supply flow path P2 defined by the gap between the hole 32a and the supply pipe 33a, and a second supply flow path P3 defined by the gap between the gas pipe 31a and the supply pipe 33a.

P1 indicated in FIG. 6 denotes a gas flow path passing through the gas pipe 31a.

The gas flow path P1 keeps the first gas room 41 in communication with the reactor 20 so that the first gas flows to the reactor 20. The first supply flow path P2 keeps the second gas room 42 in communication with the reactor 20 so that the second gas flows to the reactor 20. The second supply flow path P3 keeps the third gas room 43 in communication with the reactor 20 so that the third gas flows to the reactor 20.

To ensure formation of the gas flow path P1 and the supply flow paths P2 and P3, separation of the first gas room 41, the second gas room 42 and the third gas room 43 from one another, and easy mixture of gases, the gas pipe 31a may have a length substantially identical to a length that covers a sum of a width of the second gas room 42 and a thickness of the third supplier 33, and a sum of a width of the second gas room 42 and a thickness of the second supplier 32, respectively. Also, the supply pipe 33a may have a length substantially identical to a length that covers a sum of a width of the second gas room 42 and a thickness of the second supplier 32.

That is, an end portion of the hole 32a near the reactor 20, an end portion of the supply pipe 33a near the reactor 20, and an end portion of the gas pipe 31a near the reactor 20 may be located at substantially identical positions.

As set forth above, according to exemplary embodiments of the invention, in a chemical vapor deposition apparatus, separate gases are fed into a chamber individually. However, the apparatus overcomes a spatial limitation to allow the separate gases to be supplied in a great amount at one time. Also, the gases supplied are mixed fast to ensure more reliable deposition.

While the present invention has been shown and described in connection with the exemplary embodiments, it will be apparent to those skilled in the art that modifications and variations can be made without departing from the spirit and scope of the invention as defined by the appended claims.

What is claimed is:

1. A chemical vapor deposition apparatus comprising:
a chamber comprising a reactor where a deposition object is deposited;
a first supplier comprising a plurality of gas pipes allowing a first gas to be jetted into the reactor in a substantially horizontal direction;
a second supplier comprising a plurality of holes of a predetermined size having the gas pipes inserted therein, respectively;
a supply flow path formed between each of the gas pipes and each of the holes, the supply flow path allowing a second gas to be supplied into the reactor in a substantially horizontal direction.

2. The chemical vapor deposition apparatus of claim 1, further comprising an outlet opening provided in a center of the reactor to exhaust a reaction gas,
wherein the reactor is provided at an outer edge thereof with the first and second suppliers.

3. The chemical vapor deposition apparatus of claim 2, further comprising a first gas room provided between a side end portion of the chamber and the first supplier disposed inward from the side end portion of the chamber to have a predetermined gap therebetween.

4. The chemical vapor deposition apparatus of claim 3, further comprising a second gas room provided between the first supplier and the second supplier disposed inward from the first supplier with a predetermined gap therebetween.

5. The chemical vapor deposition apparatus of claim 4, wherein the first and second gas rooms are separated from each other by the first supplier.

6. The chemical vapor deposition apparatus of claim 4, further comprising:
at least one first inlet allowing a first gas to be introduced to the first gas room; and
at least one second inlet allowing a second gas to be introduced to the second gas room.

7. The chemical vapor deposition apparatus of claim 4, wherein the supply flow path is defined by a gap of a predetermined size between an inner surface of the hole and an outer surface of the gas pipe.

8. The chemical vapor deposition apparatus of claim 4, further comprising a third supplier disposed between the first and second suppliers, wherein the second gas room is formed between the third supplier and the second supplier and the third gas room is formed between the third supplier and the first supplier.

9. The chemical vapor deposition apparatus of claim 8, wherein the third supplier comprises a plurality of supply pipes hollowed to have the gas pipes inserted therein, each of the supply pipes allowing a third gas of the third gas room to be introduced to the reactor by keeping the third gas room and the reactor in communication with each other.

10. The chemical vapor deposition apparatus of claim 9, wherein the supply flow path comprises:
a first supply flow path formed between the each of the holes and each of the supply pipes to allow a second gas of the second gas room to be supplied, and
a second supply flow path formed between the supply pipe and the gas pipe to allow the third gas of the gas room to be supplied.

11. The chemical vapor deposition apparatus of claim 9, wherein the first supply flow path is defined by a gap of a predetermined size between an inner surface of the hole and an outer surface of the supply pipe, and
the second supply flow path is defined by a gap of a predetermined size between an inner surface of the supply pipe and an outer surface of the gas pipe.

12. The chemical vapor deposition apparatus of claim 8, further comprising at least one third inlet allowing a third gas to be introduced to the third gas room.

13. The chemical vapor deposition apparatus of claim 1, further comprising a plurality of outlet openings at an outer edge of the reactor to exhaust a reaction gas,
wherein the reactor is provided in a center thereof with the first and second suppliers.

14. The chemical vapor deposition apparatus of claim 13, further comprising a first gas room disposed inward from the first supplier.

15. The chemical vapor deposition apparatus of claim 14, further comprising a second gas room formed between the first and second suppliers, the second supplier surrounding the first supplier with a predetermined gap therebetween.

16. The chemical vapor deposition apparatus of claim 15, wherein the supply flow path is defined by a gap of a predetermined size between an inner surface of the hole and an outer surface of the gas pipe.

17. The chemical vapor deposition apparatus of claim 15, wherein the flow path is defined by a gap of a predetermined size between an inner surface of the holes and an outer surface of the gas pipes.

18. The chemical vapor deposition apparatus of claim 15, further comprising a third supplier disposed between the first and second suppliers, wherein the second gas room is formed between the third supplier and the second supplier and the third gas room is formed between the third supplier and the first supplier.

19. The chemical vapor deposition apparatus of claim 18, wherein the third supplier comprises a plurality of supply pipes hollowed to have the gas pipes inserted therein, each of the supply pipes allowing a third gas of the third gas room to be introduced to the reactor by keeping the third gas room and the reactor in communication with each other.

20. The chemical vapor deposition apparatus of claim 19, wherein the supply flow path comprises:
a first supply flow path formed between the each of the holes and each of the supply pipes to allow a second gas of the second gas room to be supplied, and
a second supply flow path formed between the supply pipe and the gas pipe to allow the third gas of the gas room to be supplied.

21. The chemical vapor deposition apparatus of claim 20, wherein the first supply flow path is defined by a gap of a predetermined size between an inner surface of the hole and an outer surface of the supply pipe, and
the second supply flow path is defined by a gap of a predetermined size between an inner surface of the supply pipe and an outer surface of the gas pipe.

22. The chemical vapor deposition apparatus of claim 15, further comprising:
a first inlet formed in communication with the first gas room and allowing the first gas to be fed to the first gas room, and
a second inlet surrounding the first inlet to have a predetermined gap therebetween, the second inlet allowing the second gas to be fed to the second gas room through the gap with the first inlet.

23. The chemical vapor deposition apparatus of claim 22, wherein the first inlet is formed integral with the first supplier and the second inlet is formed integral with the second supplier.

24. The chemical vapor deposition apparatus of claim 19, further comprising:
a first inlet formed in communication with the first gas room and allowing the first gas to be fed to the first gas room,
a second inlet surrounding the first inlet to have a predetermined gap therebetween, the second inlet formed in communication with the second gas room to allow the second gas to be fed to the second gas room, and
a third inlet inserted with a predetermined gap from the second inlet and surrounding the first inlet to have a predetermined gap therebetween, the third inlet allowing the third gas to be fed to the third gas room through the gap with the first inlet.

25. The chemical vapor deposition apparatus of claim 24, wherein the first inlet is formed integral with the first supplier, the second inlet is formed integral with the second supplier and the third inlet is formed integral with the third supplier.

26. The chemical vapor deposition apparatus of claim 14, further comprising:
a susceptor accommodating the deposition object inside the chamber; and
a rotational axis passing through the first gas room to rotate the susceptor.
